(19) United States
(12) Patent Application Publication
(10) Pub. No.: US 2025/0185195 A1
(43) Pub. Date: Jun. 5, 2025

(54) ELECTRONIC DEVICE

(71) Applicant: Lenovo (Beijing) Limited, Beijing (CN)

(72) Inventors: Ling LI, Beijing (CN); Yan LIANG, Beijing (CN)

(21) Appl. No.: 18/965,445

(22) Filed: Dec. 2, 2024

(30) Foreign Application Priority Data
Nov. 30, 2023 (CN) 202311630842.0

(51) Int. Cl. H05K 5/02

(52) U.S. Cl. CPC H05K 5/0234; H05K 5/0221

(57) ABSTRACT

An electronic device includes: a display having various structural forms; a support structure configured to carry the display to place the electronic device on a supporting surface; and a drive assembly connected to the support structure and the display, and configured to drive the display to switch to various structural forms when a relative position relationship between the display and the support structure changes. The display has different curvatures in different structural forms.

### CROSS-REFERENCE TO RELATED APPLICATION

This application claims priority to Chinese Patent Application No. 202311630842.0, filed on Nov. 30, 2023, and the entire content of which is incorporated herein by reference.

### TECHNICAL FIELD

The present disclosure relates to the technical field of electronic device structure technologies, and more particularly, to an electronic device.

### BACKGROUND

Currently, electronic devices have displays in only one form, such as either flat screens or curved screens, which cannot be adjusted according to user's needs and have a relatively simple operation state.

### SUMMARY

One aspect of the present disclosure provides an electronic device. The electronic device includes: a display having various structural forms; a support structure configured to carry the display to place the electronic device on a supporting surface; and a drive assembly connected to the support structure and the display, and configured to drive the display to switch to various structural forms when a relative position relationship between the display and the support structure changes. The display has different curvatures in different structural forms.

### BRIEF DESCRIPTION OF THE DRAWINGS

The drawings are not necessarily drawn to scale. The same reference numerals in the drawings may describe similar parts in different views. The drawings generally illustrate examples of various embodiments rather than limitations. Together with the specification and claims, the drawings serve to illustrate the disclosed embodiments. When appropriate, the same reference numerals are used throughout the drawings to refer to the same or similar parts. The embodiments of the apparatus or method are illustrative and are not intended to be exhaustive or exclusive.

FIG. 1 is a schematic structural diagram of an electronic device according to some embodiments of the present disclosure;

FIG. 2 is a process diagram of changing a structural form of a display according to some embodiments of the present disclosure;

FIG. 3 is a schematic structural diagram of a part of an electronic device according to some embodiments of the present disclosure;

FIG. 4 is a schematic structural diagram of another part of an electronic device according to some embodiments of the present disclosure;

FIG. 5 is a schematic structural diagram of another part of an electronic device according to some embodiments of the present disclosure;

FIG. 6 is a schematic structural diagram of another part of an electronic device according to some embodiments of the present disclosure;

FIG. 7 is a schematic structural diagram of another part of an electronic device according to some embodiments of the present disclosure; and

FIG. 8 is a schematic structural diagram of another part of an electronic device according to some embodiments of the present disclosure.

Numeral labels in the drawings includes: 1—display panel, 2—back cover, 3—back plate, 4—fiber layer, 5—first connection member, 6-support structure, 7—first plate, 8—second plate, 9—first rotation shaft, 10—rotation shaft base, 11—first rotation member, 12—second rotation member, 13—second rotation shaft, 14—connection rod, 15—second connection member, 16—pulling member, 17—third fixing member, 18—guide member, 19—lock structure, 20—backlight control panel, 21—touch control panel, 22—display, 23—plate structure, and 24—frame assembly.

### DETAILED DESCRIPTION OF THE EMBODIMENTS

To clearly and completely describe the technical solutions in the embodiments of the present application, the present disclosure is described in detail below in conjunction with the drawings and specific implementation methods. Obviously, the described embodiments are merely part of the embodiments of the present disclosure, not all of the embodiments. Based on the embodiments in the present disclosure, all other embodiments obtained by ordinary people skilled in the art without creative work are within the scope of protection of the present disclosure.

The accompanying drawings, which are included in and constitute a part of the specification, illustrate embodiments of the present disclosure and are used together with the general description of the present disclosure given above and the detailed description of the embodiments given below to describe the principles of the present disclosure.

These and other features of the present disclosure will become apparent from the following description of preferred forms of embodiments given as non-limiting examples with reference to the accompanying drawings.

It should also be understood that although the present disclosure has been described with reference to some specific examples, a person skilled in the art will be able to realize many other equivalent forms of the present disclosure with certainty, which have the features described in the claims and are therefore all within the scope of protection defined thereby.

The above and other aspects, features and advantages of the present disclosure will become more apparent in view of the following detailed description when combined with the accompanying drawings.

Specific embodiments of the present disclosure are described hereinafter with reference to the accompanying drawings. However, it should be understood that the disclosed embodiments are merely examples of the present disclosure, which may be implemented in a variety of ways. Well-known and/or repeated functions and structures are not described in detail to avoid unnecessary or redundant details that obscure the present disclosure. Therefore, the specific structural and functional details disclosed herein are not intended to be limiting, but are merely used as the basis and representative basis for the claims to teach those skilled in the art to use the present disclosure in a variety of ways with substantially any suitable detailed structure.

The specification may use the phrases “in one embodiment”, “in another embodiment”, “in yet another embodiment” or “in other embodiments”, which may refer to one or more of the same or different embodiments according to the present disclosure.

The embodiments of the present disclosure are described in detail below in conjunction with the accompanying drawings.

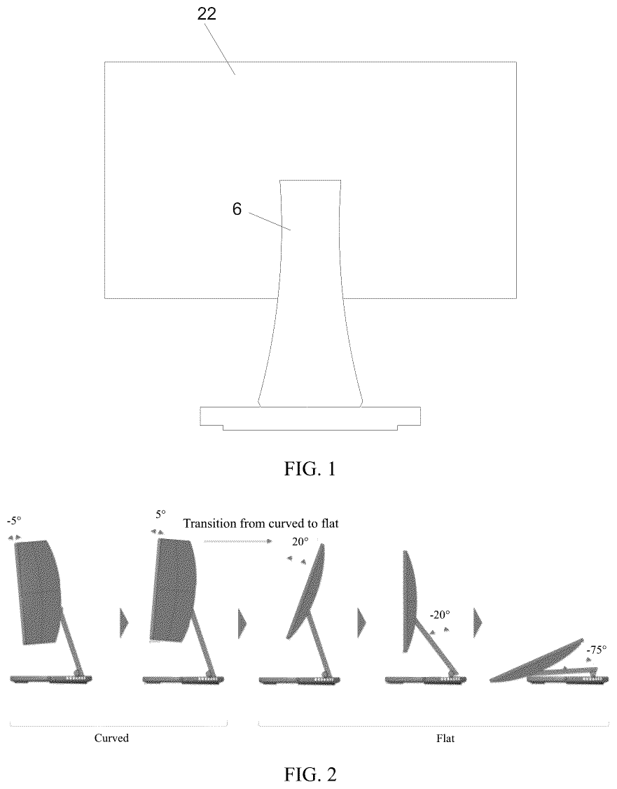

The present disclosure provides an electronic device. FIG. 1 is a schematic structural diagram of an electronic device according to some embodiments of the present disclosure. As shown in FIG. 1, the electronic device includes: a display 22, which may have various structural forms, a support structure 6 configured to carry the display 22 such that the electronic device can be placed on a supporting surface, and a drive assembly connected to the support structure 6 and the display 22. The drive assembly may drive the display 22 to switch to various structural forms when a relative position relationship between the display 22 and the support structure 6 changes. The display may have different curvatures in different structural forms.

The display 22 has structural forms including, for example, a flat state and a curved state. The display 22 may change its curvature within a certain range when the display 22 operates in the curved state. That is, the curvature/curved state may be changed according to user's operation requirements. The support structure 6 may be a support column or a support base, etc., and may be connected to the display 22 to support the display 22, such that the electronic device can be placed on a flat or inclined surface such as a desktop or a countertop, and can also be hung on a wall or a board. The form of the supporting surface is not limited in the present disclosure. For example, the support structure 6 may be a Vesa bracket.

In some embodiments, the display 22 and the support structure 6 may move relative to each other to adjust a relative position or a relative angle between the two, for example, an elevation angle and a depression angle of the display 22 relative to the support structure 6, that is, the display 22 and the support structure 6 can move relative to each other, thereby achieving different relative positions to meet the user's different angles of operation requirements for electronic devices. The drive assembly is connected to the support structure 6 and the display 22, and is used to synchronously or asynchronously drive the display 22 to show different structural forms when a change of the relative position between the display 22 and the support structure 6 occurs, such that under a current relative position relationship, the form of the display 22 matches the relative position, that is, the current curvature of the display 22 matches the relative position, which is more convenient for the user to watch the content of the display 22.

For example, when the user is playing games, working, watching videos, drawing/writing, video conferencing, etc., the display 22 is adjusted to have different relative positions relative to the support structure 6, which is equivalent to relative to the user. When the display 22 is driven to different positions, the curvature of the display 22 may also be adjusted accordingly, ensuring that the user can watch the content of the display 22 more comfortably and conveniently, and improving the operation effectiveness and user experience.

In some embodiments, when an angle between the display 22 and the support structure 6 is within a first angle range, for example, greater than or equal to 160°, the display 22 is in a first structural form, that is, in the curved state. When the angle between the display 22 and the support structure 6 is within a second angle range, for example, less than 160°, the display 22 is in a second structural form, that is, in the flat state (or a straight state). The curvature of the display 22 in the first structural form is greater than the curvature of the display 22 in the second structural form, and when the angle between the display 22 and the support structure 6 changes from the first angle range to the second angle range, the drive assembly may drive the display 22 to switch from the first structural form to the second structural form. Alternatively, when the angle between the display 22 and the support structure 6 changes from the second angle range to the first angle range, the drive assembly may drive the display 22 to switch from the second structural form to the first structural form. That is, when the display 22 rotates to different angle ranges relative to the support structure 6, the structural form of the display 22 will deform correspondingly, either in the curved state or in the flat state.

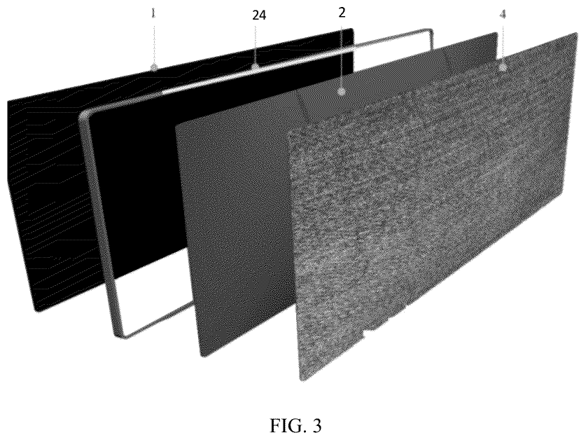

FIG. 2 is a process diagram of changing a structural form of a display according to some embodiments of the present disclosure. As shown in FIG. 2, when the form of operating the electronic device is limited by the operation scenario of the electronic device, the electronic device may have the following forms of operating the electronic device.

In Form 1, the angle of the display 22 relative to the support structure 6 may be adjusted in a range from −5° to 5°. In this case, the display 22 is in a curved screen mode, which is more suitable for the operation scenarios such as games and entertainment.

In Form 2, the angle of the display 22 relative to the support structure 6 may be adjusted in a range from 5° to 30°. In this case, the display 22 changes from the curved screen mode to a flat screen mode, which is more suitable for the operation scenarios such as office, casual entertainment, video editing, etc.

In Form 3, the angle of the display 22 relative to the support structure 6 may be set to 0°, and the display 22 is pressed downward to make the angle between the support structure 6 and the supporting surface be 45°. The display 22 changes from the curved screen mode to the flat screen mode, which is more suitable for the operation scenarios such as office, casual entertainment, video editing, etc.

In Form 4, the angle of the display 22 relative to the support structure 6 may be set to 140°, and the support structure 6 is pressed downward to form an angle of −75° with the supporting surface. In this case, the display 22 is in the flat screen mode, which is more suitable for the operation scenario where the user draws on the screen of the display 22 and multiple users interact with the display content of the display 22.

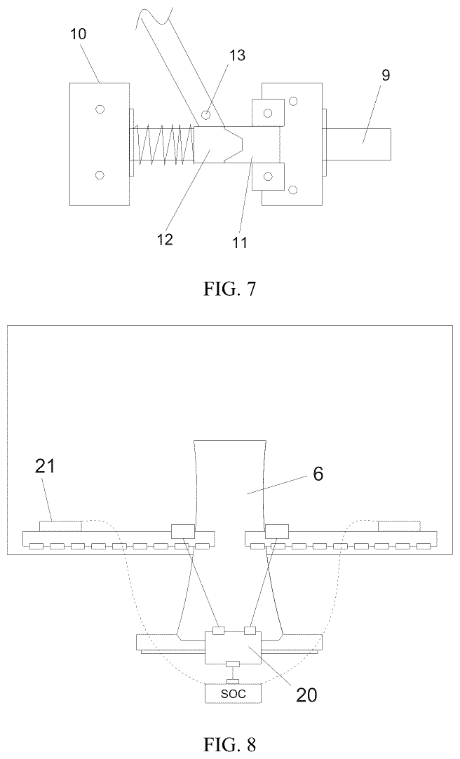

Further, as shown in FIGS. 1-7, the display 22 of the present disclosure includes a display panel 1, a back cover 2 covering the display panel 1, and a back plate 3 arranged on the back of the display panel 1 for supporting the display panel 1. The display panel 1 may be, for example, but not limited to, an LED screen, an OLED screen, a mini-LED screen, or an LCD screen. The display panel 1 may be a hard structure, such as a hard screen, including the display panel 1 in the form of a whole screen panel, or a tri-fold screen. The display panel 1 may also be a flexible screen/curved screen. The specific structure of the back cover 2 is not limited, as long as it can protect the display panel 1 and the material thereof supports a structure with bending deformation within a certain range.

In some embodiments, the back cover 2 includes a frame assembly 24 that meets the above conditions, and also includes other plates located on the front side or the back side of the display panel 1 and attached to the display panel 1 to protect the display panel 1. For example, a glass plate may be configured on the front side of the display panel 1. In another example, a reinforcing plate, a support plate, etc. may be configured on the back side of the display panel 1. The present disclosure does not limit the specific structure of the back cover 2, which may be determined according to actual needs. When the display 22 is deformed and bent, the frame assembly 24 in the back cover 2, for example, may also bend synchronously in a portion corresponding to the bending of the display 22. The material of the portion used for bending in the frame assembly 24 may be different from the material of other portions. Alternatively, the frame assembly 24 as a whole may be made of a bendable material.

The back plate 3 is arranged on the back side of the display panel 1. The back plate 3 is arranged opposite to a side of a backlight plate of the display panel 1 facing away from the display panel 1. A decorative layer, such as a patch, may also be installed outside the display 22. In some embodiments, a fiber layer 4 may also be provided on the outermost side of the display 22. The back plate 3 also has a certain elastic bending ability, such that it can change with the display panel 1 to have different curvatures. The specific material there is not limited by the present disclosure. The back cover 2 may change accordingly as the back plate 3 changes its shape, such that the display 22 has different structural forms.

As shown in FIGS. 1-7, the electronic device further includes a plate structure 23 arranged between the back plate 3 and the back cover 2 and a rotation shaft structure arranged on the plate structure 23. The drive assembly is arranged on the plate structure 23 and connected to the back plate 3 through at least one first connection member 5. The drive assembly and the support structure 6 are movably connected through the rotation shaft structure. When the relative position between the display 22 and the support structure 6 changes, the rotation shaft structure may trigger the drive assembly to drive at least part of the back plate 3 to approach or move away from the plate structure 23 through the first connection member 5, such that the display 22 has different structural forms.

The plate structure 23 is located in an area surrounded by the back cover 2 and the back plate 3. The plate structure 23 is arranged to carry the drive assembly and provide support for the display panel 1 and the back cover 2 as a whole, such that it can stably adjust the shape and curvature. A gap is arranged between the plate structure 23 and the back plate 3 to provide a deformation space for the back plate 3 and the display panel 1.

In some embodiments, the drive assembly is arranged on the plate structure 23 and connected to the back plate 3 through at least one first connection member 5. The number of the at least one first connection member 5 is not limited by the present disclosure and may be determined comprehensively according to a driving force of the drive assembly and the area of the display panel 1. The rotation shaft structure is also connected to the plate structure 23. The drive assembly and the support structure 6 are connected through the rotation shaft structure to facilitate relative movement. For example, the support structure 6 facilitates the relative movement with the rotation shaft structure. That is, the support structure 6 moves relative to the display 22 through the rotation shaft structure, thereby driving the drive assembly to move. In another example, the display 22 may facilitate relative rotation with the support structure 6 based on the rotation shaft structure to adjust its relative position with the support structure 6. When the display 22 and the support structure 6 move relatively, the drive assembly may be driven to move. Because the drive assembly is connected to the back plate 3 through the at least one first connection member 5, the movement of the drive assembly may transmit the driving force to the back plate 3 through the at least one first connection member 5, such that it can drive the display 22 to adjust its shape, including driving the display panel 1 through the back plate 3 to deform at least part of the display 22 in a direction of approaching or moving away from the plate structure 23, for example, making the display 22 partially or as a whole bulge in a direction facing away from a display side. The greater the degree of bulging, the greater the curvature of the display 22, thereby causing the display 22 to have different curvatures and different structural forms.

The specific bending position of the display 22 may be determined by a connection position of the at least one first connection member 5 and the back plate 3, such as being consistent with the connection position of the at least one first connection member 5, or with an area surrounded by multiple first connection members 5, etc. Alternatively, the bending position of the display 22 is determined by the connection position of the plate structure 23 relative to the back panel 3, because the plate structure 23 has the effect of supporting the display 22, that is, providing a support point for the entire plane of the display 22 such that it can stably change its shape. Therefore, if the plate structure 23 is connected to both ends of the display 22, it means that the support points are located at both ends of the display 22, and the bent portion is the entire display 22. If the plate structure 23 is connected to a middle area of the display 22, that is, the area covered by the plate structure 23 of the display 22 is located in the middle area of the display 22, then the support point is located at an edge of the middle area, and the bending position of the display 22 is located in the area covered by the plate structure 23. The area located at the support point and the end of the display 22 will change its shape with the deformation and inertial tension of the back panel 3.

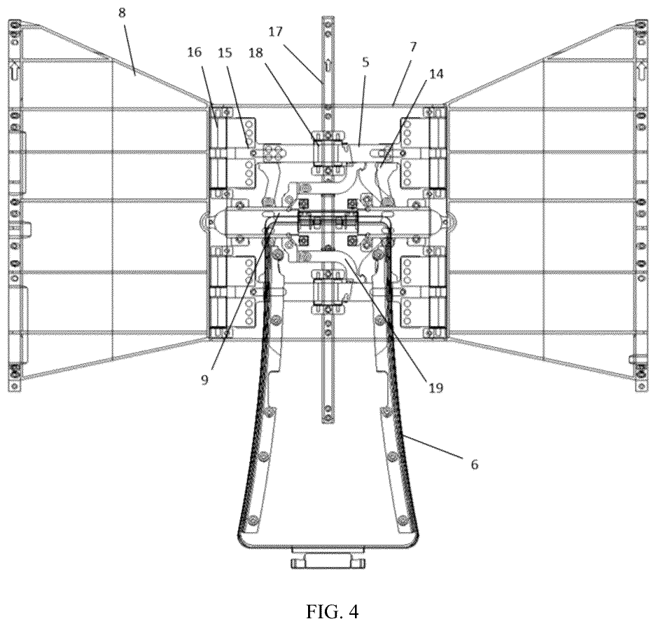

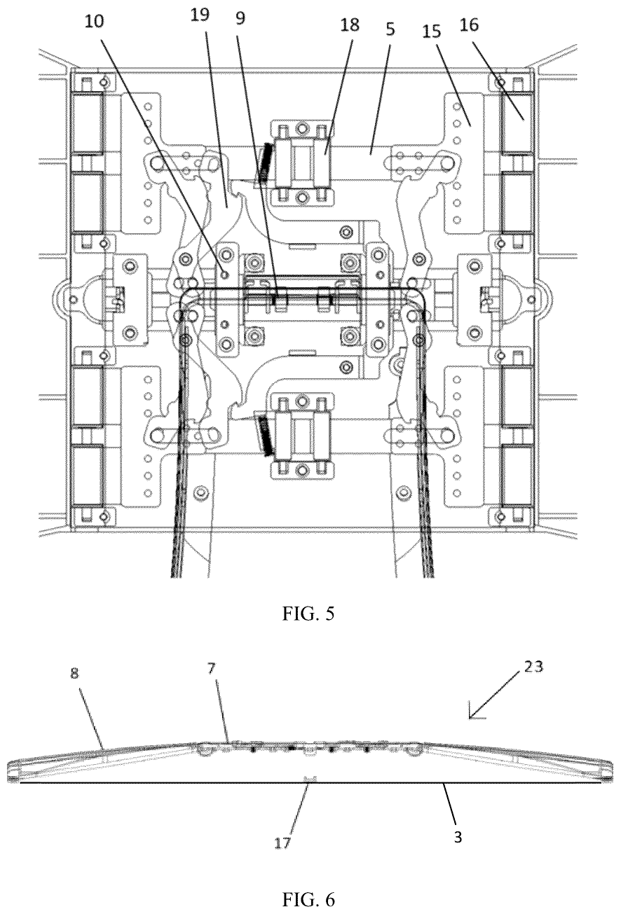

In some embodiments, as shown in FIG. 4 and FIG. 5, the plate structure 23 includes a first plate 7 and two second plates 8 arranged on opposite sides of the first plate 7. A first angle is formed between the first plate 7 and each of the two second plates 8. The specific angle value of the first angle is not limited by the present disclosure and may depend on the length of the display 22 and the connection positions between the two second plates 8 and the back plate 3. In some embodiments, the first plate 7 and the two second plates 8 are enclosed to form a trapezoid shape.

The two opposite edges of the back plate 3 are respectively provided with first fixing members, and the edges of the two second plates 8 facing away from the first plate 7 are respectively fixedly connected to the two first fixing members. For example, one or more first fixing members are respectively provided at the edges of the opposite sides of the back plate 3 (taking the display panel 1 and the back plate 3 as a rectangle as an example, the opposite sides are the two sides in a length direction of the back plate 3), or at the adjacent edges. When there are multiple first fixing members, the multiple first fixing members may be arranged along the length direction of the edge of the back plate 3, for example, evenly arranged, and the intervals may be but not limited to about 6.5 cm. The ends of the two second plates 8 that are not connected to the first plate 7 are respectively connected to the first fixing members located at the edges of both sides of the back plate 3. When in operation, the plate structure 23 may be set in a direction perpendicular to the display panel 1, and a projection of the back plate 3 and a projection of the plate structure 23 are correspondingly overlapped, or at least in the length direction of the display 22, the projection of the plate structure 23 matches the projection of the back plate 3. In a width direction, the projection of the plate structure 23 may be smaller than the projection of the back plate 3. The structure of the first fixing member may be an assembly hole, a snap-fit structure, a welding point, an adhesive point, etc. To facilitate the connection with the first fixing member, each of the two second plates 8 extends horizontally outward at its edge to form an extension portion to be connected to the first fixing member based on the extension part. For example, the extension portion is provided with a structure matching the first fixing member, or is welded together with the first fixing member.

In some embodiments, the back plate 3 is provided with second fixing members at the two second plates 8, respectively. The number and structure of the second fixing members are not limited by the present disclosure. For specifics, reference can be made to that of the first fixing members. Different from the previous embodiments, the second fixing members are not configured at the edges of the opposite sides of the back plate 3, but rather in the middle of the back plate 3, that is, between the two sides, and is not adjacent to the edge of the back plate 3, that is, the positions of two sets of second fixing members are arranged respectively at a certain distance from the corresponding edges of the back plate 3. The distance does not fall into the ranges of adjacent edges. In addition, the positions of the two sets of second fixing members are arranged symmetrically, for example, with respect to the midline position of the back plate 3. The side edges of the two second plates 8 that are not connected to the first plate 7 are respectively fixedly connected to the corresponding second fixing members. Similarly, for the convenience of connection, the edge of each of the two second plates 8 may also be extended to form an extension portion to match and connect with the second fixing members based on the extension portion. For the specific connection method, reference can be made to the connection between the corresponding extension portion and the first fixing member.

In addition, in some embodiments, the structural shapes of the two second plates may also be different, such that the fixing members are configured at two asymmetric positions of the back plate 3 and are respectively fixedly connected to the two second plates, such that the display 22 has an asymmetric curvature change.

The drive assembly is arranged on the first plate 7, and is connected to the back plate 3 corresponding to the first plate 7 through the at least one first connection member 5, to drive the display 22 to bend and form the first structural form. When the display 22 is in the first structural form, that is, in the curved state, and the curvature is not 0, the portion of the back plate 3 corresponding to the first plate 7 is bulged and curved. At this time, a minimum distance between the portion of the back plate 3 corresponding to the first plate 7 and the first plate 7 is the first distance. That is, a distance between a vertex of the curved portion of the back plate 3 and the first plate 7 is minimum, which is the first distance. The specific value of the first distance is not limited by the present disclosure. For example, the first distance may be but not limited to 0.3 cm, 0.2 cm, etc. When the display 22 is restored from the curved state to the flat state, that is, in the second structural form, the portion of the back plate 3 corresponding to the first plate 7 has a maximum distance with respect to the first plate 7, and the maximum distance is a second distance. The second distance is greater than the first distance, and the value of the second distance may be, for example, but not limited to 3 cm, 2 cm, etc.

Further, in some embodiments, the rotation shaft structure includes a first rotation shaft 9, a rotation shaft base 10 disposed on the first plate 7 for assembling the first rotation shaft 9, and a first rotation member 11 sleeved on the first rotation shaft 9, fixedly connected to the first plate 7, and movably connected to the drive assembly. When the support structure 6 rotates relative to the display 22, the first rotation member 11 may generate a force on the drive assembly, such that the drive assembly can pull the back plate 3 toward the first plate 7 or restore the back plate 3 to its initial shape through the at least one first connection member 5.

In some embodiments, as shown in FIG. 4 and FIG. 6, the rotation shaft base 10 is installed on the side of the first plate 7 facing away from the display panel 1, and includes a first base and a second base that are separated apart from each other. The first rotation shaft 9 penetrates through the first base and the second base. The first base and the second base may rotate relative to the first rotation shaft 9 when the display 22 rotates relative to the support structure 6. That is, the first rotation shaft 9 is fixed in position, and the rotation shaft base 10 may rotate relative to the first rotation shaft 9 as the display 22 rotates, that is, the display 22 rotates relative to the support structure 6. One end of the first rotation shaft 9 is also connected to the support structure 6. For example, a mounting hole may be configured on the support structure 6 to connect the first rotation shaft 9. The first rotation member 11 is sleeved on the first rotation shaft 9 between the first base and the second base. The first rotation member 11 is fixedly connected to the first plate 7 and may rotate relative to the first rotation shaft 9. The drive assembly is movably connected to the first rotation member 11. When the display 22 rotates relative to the support structure 6, the first plate 7 drives the first rotation member 11 to rotate synchronously. The rotating first rotation member 11 may generate a force against the drive assembly. Based on the force, the drive assembly may pull the back plate 3 toward the first plate 7 or restore the back plate 3 to its initial form, i.e., the flat state (or the second structural form) through the at least one first connection member 5. Alternatively, the first rotation shaft 9 is connected to the support structure 6 and is connected to the first plate 7 through the rotation shaft base 10. The first rotation member 11 is fixedly connected to the support structure 6. When the support structure 6 is driven to rotate, it will drive the first rotation member 11 to rotate relative to the first rotation shaft 9, thereby generating the force between the first rotation member 11 and the drive assembly.

Referring to FIG. 4 and FIG. 6, the drive assembly further includes a second rotation member 12 sleeved on the first rotation shaft 9, movably connected to the first rotation member 11, and capable of moving in an axial direction of the first rotation shaft 9 under the force of the first rotation member 11. The drive assembly further includes a pulling sub-assembly movably arranged on the first plate 7, connected to a first end of the at least one first connection member 5, capable of applying a force to the at least one first connection member 5 to make the back plate 3 approach or move away from the first plate 7. The drive assembly further includes a transmission sub-assembly connecting the second rotation member 12 and the pulling sub-assembly, used to transmit a force to the pulling sub-assembly when the second rotation member 12 moves, to drive the pulling sub-assembly to move.

In some embodiments, the second rotation member 12 is sleeved on the first rotation shaft 9 and elastically connected to the base disposed away from the first rotation member 11. For example, a spring is sleeved on the first rotation shaft 9. One end of the spring is connected to the corresponding base, and the other end is connected to the second rotation member 12, to limit the second rotation member 12 on the first rotation shaft 9 and allow the second rotation member 12 to move axially on the first rotation shaft 9. The second rotation member 12 and the first rotation member 11 have a structure for interacting with each other to generate a force for pushing the second rotation member 12 to move. For example, the first rotation member 11 and the second rotation member 12 have a concave-convex coupling structure. When the display 22 is in the flat state, the concave-convex coupling structure is in an engaged state. When the first rotation member 11 rotates, the convex portion on the first rotation member 11 may push the second rotation member 12 to move in a direction of a compression spring, such that the convex portion and the concave portion are separated, providing a rotation space for the rotation of the first rotation member 11 and removing any obstruction. When the first rotation member 11 rotates and resets, the convex portion of the first rotation member 11 couples to the concave portion. At this time, the second rotation member 12 moves in the direction of an extension spring under an elastic force of the extension spring, such that the concave portion and the convex portion are in the engaged state again. This completes a process of the second rotation member 12 reciprocating along the first rotation shaft 9, and the corresponding display 22 completes mutual transformation between the first structural form and the second structural form. In practical application, the first rotation member 11 and the second rotation member 12 may be configured as a cam and concave structure, or a concave and cam structure, as long as the convex and concave portions on the two rotation members can couple with each other to limit the position and can rotate and separate relative to each other. A height or a depth of the convex and concave portions determines a moving distance of the second rotation member 12 on the first rotation shaft 9. The moving distance is related to a maximum curvature generated by the deformation of the display 22. Therefore, the size of the convex and concave portions may be adjusted accordingly according to the requirements of the curvature range of the display 22 during fabrication.

The pulling sub-assembly is arranged on the first plate 7 and may move relative to the first plate 7. The at least one first connection member 5 has a first end and a second end. The first end is connected to the pulling sub-assembly, and the second end is connected to the back plate 3. The transmission sub-assembly is respectively connected to the second rotation member 12 and the pulling sub-assembly, to transmit the force generated to the pulling sub-assembly when the second rotation member 12 moves along a first axis, such that the pulling sub-assembly moves relative to the first plate 7, and then pulls the back plate 3 and the display panel 1 through the at least one first connection member 5 to deform in a direction approaching or moving away from the first plate 7, thereby changing the curvature of the display 22.

In some embodiments, the transmission sub-assembly includes a connection rod 14 and a second rotation shaft 13 disposed on the first plate 7. The connection rod 14 rotates through the second rotation shaft 13. For example, a portion of the connection rod 14 adjacent to one end thereof facing toward the second rotation member 12 is connected to the second rotation shaft 13. In another example, a middle portion of the connection rod 14 is connected to the second rotation shaft 13. When the connection rod 14 has a fixed length, the connection position of the connection rod 14 and the second rotation shaft 13 determines a movement stroke of the end of the connection rod 14. The two opposite ends of the connection rod 14 are respectively connected to the second rotation member 12 and the pulling sub-assembly. When the second rotation member 12 moves in the first direction along the first axis, the second rotation member 12 drives one end of the connection rod 14 to move in the first direction. At this time, the connection rod 14 rotates relative to the second rotation shaft 13, such that the other end of the connection rod 14 drives the pulling sub-assembly to move in a second direction. When the second rotation member 12 moves in the second direction, the connection rod 14 may transmit a force in the first direction to the pulling sub-assembly to drive the pulling sub-assembly to move in the first direction. The first direction is opposite to the second direction, such that the pulling sub-assembly can move forward and backward in a direction of pulling the back plate 3 to achieve pulling the back plate 3 and the display panel 1 to deform in the direction approaching or moving away from the first plate 7.

The pulling sub-assembly includes a second connection member 15 movably connected to the connection rod 14 of the transmission sub-assembly and at least one pulling member 16 connected to the second connection member 15. In some embodiments, the second connection member 15 is fixedly connected to the first end of the at least one first connection member 5, and the other end is connected to the at least one pulling member 16. The at least one pulling member 16 may apply a force in the first direction to the second connection member 15, that is, the at least one pulling member 16 may provide the second connection member 15 with an increased force to pull the back plate 3, that is, providing an auxiliary force to pull the back plate 3. The second connection member 15 may move along the first direction and the second direction when being driven by the connection rod 14. When the second connection member 15 moves in the first direction, the second connection member 15 is pulled by the at least one pulling member 16 at the same time. That is, when the second connection member 15 moves in the first direction, it is subject to a joint force of the connection rod 14 and the at least one pulling member 16. When the second connection member 15 moves in the first direction and the second direction, the second connection member 15 may apply a force to the at least one first connection member 5, thereby changing the structural form of the back plate 3 and the display panel 1.

In practical applications, for example, the at least one first connection member 5 may be a steel belt. A through-hole is provided on the first plate 7, and a second end of the at least one first connection member 5 penetrates through the through-hole and is connected to the back plate 3. The second connection member 15 is a movable plate including a plurality of connection parts. The connection part located on a first side of the movable plate is connected to the at least one first connection member 5, and the connection part located on a second side of the movable plate is connected to the at least one pulling member 16, and the number of the connection parts matches the number of the corresponding first connection member 5 and the at least one pulling member 16, which is not limited by the present disclosure. The at least one pulling member 16 may be a constant force spring, for example, a coil spring, one end of which is fixed on the first plate 7, and the other end is connected to the corresponding connection part on the second connection member 15. When the second connection member 15 drives the at least one pulling member 16 to move in the second direction, the display 22 is in the second structural form, that is, the flat state, and the at least one pulling member 16 is in a stretched state and has a large elastic stress. When the second connection member 15 moves in the first direction, even if the display 22 is in the first structural form. That is, in the curved state, the at least one pulling member 16 drives the second connection member 15 to move in the first direction based on elastic stress, such that the stable bending deformation of the display 22 can be quickly achieved.

As shown in FIG. 5, the portion of the back plate 3 corresponding to the first plate 7 is provided with a third fixing member 17. In some embodiments, the third fixing member 17 is located at the midline of the back plate 3 and is a strip-shaped structure arranged along the midline, such as a U-shaped sheet metal. Of course, the structure of the third fixing member 17 is not limited thereto by the present disclosure, and may also be a welding portion, an adhesive portion, an anchor point, etc. Moreover, there may be multiple third fixing members 17, which is not limited by the present disclosure. The number of the multiple third fixing members 17 may be determined according to the size of an area occupied by the display 22, the number and the size of the areas to be bent, etc. If the size of the area is large or the number of the areas to be bent is large, multiple third fixing members 17 may be provided. If the size of the area to be bent is small or the number of the areas to be bent is small, a small number may be provided. The third fixing member 17 is fixedly connected to the second end of the at least one first connection member 5, and the specific connection position may be determined according to a best force point determined by analyzing the force points of the back plate 3 as a whole. The best force point varies with the number of the at least one first connection member 5 provided. The at least one first connection member 5 applies a tension force to the back plate 3, the back cover 2, and the display panel 1 by applying the tension force to the third fixing member 17, forcing them to deform and bend.

To facilitate the at least one first connection member 5 to pull the third fixing member 17, reduce friction, and maintain a stable pulling direction, a guide member 18 for guiding a movement path of the at least one first connection member 5 is also provided on the first plate 7. For example, the guide member 18 may be a guide shaft or a pulley. The guide shaft may be arranged at the edge of the through-hole, and the steel belt penetrates the through-hole through the guide shaft to connect to the third fixing member 17.

Further, in response to the demand for a large screen, when the size of the display 22 is made larger, its weight will also increase accordingly. To ensure stable driving of the display 22 to deform and change the structural form, the rotation shaft structure includes the first rotation shaft 9 and the second rotation shaft 13, and the drive assembly includes a first drive assembly and a second drive assembly. The first rotation shaft 9 and the first drive assembly are arranged in a first area on the first plate 7, the second rotation shaft 13 and the second drive assembly are arranged in a second area on the first plate 7, and the first area and the second area are symmetrically arranged on both sides of a center line of the first plate 7. That is, when driving the same back plate 3, the back cover 2, and the display panel 1, two sets of the rotation shaft structures and the drive assemblies are used. The two sets of the rotation shaft structures and the drive assemblies and connection relationships thereof are the same. However, they are configured in opposite directions, and they are mirror-symmetrical. In actual applications, the two sets of the structures may be configured in multiple pairs. As shown in the drawings, two pairs of the structures are configured, such that the back plate 3, the back cover 2, and the display panel 1 are pulled based on four pulling points, that is, the pulling of the back plate 3, etc. is achieved based on four first connection members 5.

In some other embodiments, the above two sets of the structures may also be designed in an asymmetric form. For example, the two sets of the structures may be staggered in a horizontal direction, dividing the first plate 7 into left and right areas. The structure formed by the first rotation shaft and the first drive assembly may be configured in the left area, and the height of the structure on the first plate 7 is a first height. The structure formed by the second rotation shaft and the second drive assembly may be configured in the right area, and the height of the structure on the first plate 7 is a second height. The first height is different from the second height. The specific height difference and height values are not limited by the present disclosure, which can be determined according to the actual device size.

To ensure that the display panel 1 maintains the flat state when the display 22 is rotated to the angle range corresponding to the second structural form, the electronic device further includes a lock structure 19 movably connected to the drive assembly, such that the display 22 is locked in the second structural form based on the lock structure 19. Taking the first drive assembly as an example, the lock structure 19 includes a locking rod connected to the first plate 7 based on a third axis, and one end of the locking rod is simultaneously connected to the second rotation member 12, such that it can be driven to rotate as the second rotation member 12 rotates. The locking rod includes a bending portion at one end, and the other end includes a first locking portion. The connection rod 14 located on the second drive assembly is provided with a second locking portion. The first locking portion and the second locking portion may be connected in cooperation and may be separated from each other. When the display 22 switches from the curved state to the flat state, the locking rod and the corresponding connection rod 14 rotate close to each other until the first locking portion and the second locking portion engage with each other, and the display 22 is locked in the flat state. When the display 22 is bent, rotating the display 22 rotates the rotation shaft and drives the locking rod and the corresponding connection rod 14 to rotate away from each other, such that the first locking portion and the second locking portion are made to disengage and separate from each other. In some embodiments, the first locking portion and the second locking portion both may be hooks.

As shown in FIG. 8, the display 22 further includes a backlight control panel 20 for controlling display parameters of the display panel 1 and/or a touch control panel 21 for controlling touch parameters of the display panel 1. The backlight control panel 20 may be arranged on a main part of the support structure 6 on the back cover 2 or the back plate 3 of the display 22. The touch control panel 21 may be arranged in the support structure 6. Through the above arrangement, when the display 22 is in the curved state, the deformation of the display 22 will not affect the backlight control panel 20 or the touch control panel 21, ensuring that they will not be damaged or mis-touched due to substantial bending of the back plate 3.

The above embodiments are merely exemplary embodiments of the present disclosure and are not intended to limit the present disclosure. The scope of protection of the present disclosure is defined by the claims. Those skilled in the art may make various modifications or equivalent substitutions to the present disclosure within the essence and scope of the present disclosure, and such modifications or equivalent substitutions shall also be deemed to fall within the scope of the present disclosure.

What is claimed is:

1. An electronic device, comprising:
a display having various structural forms;
a support structure configured to carry the display to place the electronic device on a supporting surface; and
a drive assembly connected to the support structure and the display, and configured to drive the display to switch to various structural forms when a relative position relationship between the display and the support structure changes;
wherein the display has different curvatures in different structural forms.

2. The electronic device according to claim 1, wherein:
the display includes a display panel, a back cover covering the display panel, and a back plate arranged on the back of the display panel for supporting the display panel; and
the electronic device further includes:
a plate structure arranged between the back plate and the back cover, the drive assembly being arranged on the plate structure and connected to the back plate through at least one first connection member; and
a rotation shaft structure arranged on the plate structure, the drive assembly and the support structure being movably connected through the rotation shaft structure;
wherein when a change of the relative position between the display and the support structure occurs, the rotation shaft structure triggers the drive assembly to drive at least part of the back plate to approach or move away from the plate structure through the at least one first connection member, such that the display has different structural forms.

3. The electronic device according to claim 2, wherein:
the plate structure includes a first plate and two second plates arranged on opposite sides to the first plate, a first angle being formed between the first plate and each of the two second plates;
two opposite edges of the back plate are respectively provided with first fixing members, and two edges of each of the two second plates facing away from the first plate are respectively fixedly connected to the two first fixing members; or the back plate is provided with second fixing members at the two second plates, respectively, and two edges of the two second plates facing away from the first plate are respectively fixedly connected to the two second fixing members;
when the display is in a first structural form, a minimum distance between a portion of the back plate corresponding to the first plate and the first plate is a first distance; and
when the display is in a second structural form, a maximum distance between the portion of the back plate corresponding to the first plate and the first plate is a second distance, the second distance is greater than the first distance.

4. The electronic device according to claim 3, wherein the rotation shaft structure comprises:
a first rotation shaft;
a rotation shaft base disposed on the first plate for supporting the first rotation shaft to rotate; and
a first rotation member sleeved on the first rotation shaft, fixedly connected to the support structure or the first plate, and movably connected to the drive assembly;
when the support structure rotates relative to the display, the first rotation member generates a first force on the drive assembly, such that the drive assembly pulls the back plate toward the first plate or restores the back plate to its initial shape through the at least one first connection member.

5. The electronic device according to claim 4, wherein the drive assembly includes:
a second rotation member sleeved on the first rotation shaft, movably connected to the first rotation member, and capable of moving in an axial direction of the first rotation shaft under the first force of the first rotation member;
a pulling sub-assembly movably arranged on the first plate, connected to a first end of the at least one first connection member, and capable of applying a second force to the at least one first connection member to make the back plate approach or move away from the first plate; and
a transmission sub-assembly connecting the second rotation member and the pulling sub-assembly, used to transmit a third force to the pulling sub-assembly when the second rotation member moves, to drive the pulling sub-assembly to move.

6. The electronic device according to claim 5, wherein:
the transmission sub-assembly includes a connection rod and a second rotation shaft disposed on the first plate, the connection rod rotating through the second rotation shaft;
two opposite ends of the connection rod are respectively connected to the second rotation member and the pulling sub-assembly;
when the second rotation member moves in a first direction, the connection rod transmits a fourth force to the pulling sub-assembly in a second direction to drive the pulling sub-assembly to move in the second direction;
when the second rotation member moves in the second direction, the connection rod transmits a fifth force to the pulling sub-assembly in the first direction to drive the pulling sub-assembly to move in the first direction; and
the first direction is opposite the second direction.

7. The electronic device according to claim 5, wherein:
the pulling sub-assembly includes a second connection member movably connected to the connection rod of the transmission sub-assembly and at least one pulling member connected to the second connection member, and the at least one pulling member applies a sixth force in the first direction to the second connection member; and
the second connection member is fixedly connected to the first end of the at least one first connection member, and is driven by the connection rod to apply a pulling force to the at least one first connection member in the first direction or the second direction.

8. The electronic device according to claim 1, wherein:
when an angle between the display and the support structure is within a first angle range, the display is in a first structural form;
when the angle between the display and the support structure is within a second angle range, the display is in a second structural form; and
a curvature of the display in the first structural form is greater than a curvature of the display in the second structural form.

9. The electronic device according to claim 8, wherein:
when the angle between the display and the support structure changes from the first angle range to the second angle range, the drive assembly drives the display to switch from the first structural form to the second structural form; and
when the angle between the display and the support structure changes from the second angle range to the first angle range, the drive assembly drives the display to switch from the second structural form to the first structural form.

10. The electronic device according to claim 2 further comprising a lock structure, wherein:
the lock structure locks the display in a second structural form.

11. The electronic device according to claim 2 further comprising a lock structure, wherein:
the back cover changes as a shape of the back plate changes, such that the display has different structural forms.

12. The electronic device according to claim 2 further comprising a lock structure, wherein:
a fiber layer is provided on the back of the back cover facing away from the display panel.

13. The electronic device according to claim 2 further comprising a lock structure, wherein:
the display also includes a backlight control panel for controlling display parameters of the display panel and/or a touch control panel for controlling touch parameters of the display panel, the backlight control panel is arranged on a main part of the support structure on the back cover or the back plate of the display, and/or the touch control panel is arranged in the support structure.

14. The electronic device according to claim 3, wherein:
a portion of the back plate corresponding to the first plate is provided with a third fixing member, the third fixing member is fixedly connected to a second end of the at least one first connection member, and when a tension force is applied to the at least one first connection member, the tension force is applied to the back plate through the third fixing member.

15. The electronic device according to claim 3, wherein:
a guide member for guiding a movement path of the at least one first connection member is provided on the first plate.

16. The electronic device according to claim 3, wherein:
the rotation shaft structure includes a first rotation shaft and a second rotation shaft, the drive assembly includes a first drive assembly and a second drive assembly, the first rotation shaft and the first drive assembly are arranged in a first area on the first plate, the second rotation shaft and the second drive assembly are arranged in a second area on the first plate, and the first area and the second area are symmetrically arranged on both sides of a center line of the first plate.
